(19) United States
(12) Patent Application Publication
(10) Pub. No.: US 2020/0026187 A1
(43) Pub. Date: Jan. 23, 2020

(54) STABLE PHOTORESIST COMPOSITIONS COMPRISING ORGANOSULPHUR COMPOUNDS

(71) Applicant: SUN CHEMICAL CORPORATION, Parsippany, NJ (US)

(72) Inventors: Peter James Wilkinson, Midsomer Norton (GB); Edward Keith Mateer, Midsomer Norton (GB); Stephen Hall, Wells (GB); Derek Ronald Illsley, Frome (GB)

(73) Assignee: SUN CHEMICAL CORPORATION, Parsippany, NJ (US)

(21) Appl. No.: 16/497,568

(22) PCT Filed: Apr. 10, 2018
(86) PCT No.: PCT/US2018/026846

§ 371 Date: Sep. 25, 2019

Related U.S. Application Data
(60) Provisional application No. 62/484,467, filed on Apr. 12, 2017.

(51) Int. Cl. G03F 7/038; G03F 7/039; H05K 3/00

(52) U.S. Cl. CPC G03F 7/038; G03F 7/168; H05K 3/0076; G03F 7/039

(57) ABSTRACT

The present invention provides a photoresist composition Part A, comprising a carboxylic functional ethylenically unsaturated resin having an acid value equal to or greater than 10 mg KOH/g, and an organosulphur compound. The photoresist composition may further comprise a Part B, comprising a resin that may react with the carboxylic groups of Part A. The photoresist compositions are shelf-stable, alkali developable, and provide cured resists with improved surface- and through-cure, improved gloss, and reduced undercut and overcut.

### CROSS-REFERENCE TO RELATED APPLICATIONS

This application claims priority to U.S. Provisional Patent Application No. 62/484,467, filed 12 Apr. 2017, which is hereby incorporated by reference in its entirety.

### FIELD OF THE INVENTION

The present invention is related photoresist compositions comprising a carboxylic-functional ethylenically unsaturated resin and an organosulphur compound. In some embodiments, the photoresist composition comprises a second component, wherein the second component comprises a resin that may react with the carboxylic-functional groups of the first component. The photoresist compositions of the present invention are shelf-stable, exhibit improved cure, and are developable using a dilute aqueous alkaline solution.

### BACKGROUND

Electronic devices, such as printed circuit boards (both rigid and flexible) and solar cells, and the like, must have well-defined conductive areas. In some instances, a device is entirely coated with a conductive material, such as an aluminum or silver paste. The parts that will not form the conductive pattern are then removed, by, for example, an acid etch. In another method, the conductive pattern is formed by applying a conductive material, such as a metal solder, in the desired pattern. Without any protective coating on the areas not to be treated (i.e. etched or soldered), the conductive pattern may not be well-defined, leading to reduced performance of the electronic device.

To overcome these problems, photoresists (i.e. etch resists or solder resists) are often applied to protect areas that will form the conductive pattern, in the case of etch resists, or that will not form the conductive pattern, in the case of solder resists. A photoresist is generally an ink or coating that is applied to the electronic device substrate, cured, and uncured portions are removed by a dilute aqueous alkali solution (developing solution) to leave the desired pattern.

In certain instances, the photoresist is applied to the entire surface of the substrate. Then a mask is placed over the printed substrate so that masked (i.e. covered) portions are not exposed to the UV energy during curing. The printed and cured substrate is then developed with a dilute alkaline solution so that the uncured portions are removed. The cured portions that remain protect the surface of the substrate from either the etching or soldering treatment. When the etching or soldering is complete, the photoresist is then removed in a next step, leaving the conductive pattern on the electronic substrate.

Typically, the photoresist is applied to the substrate, a phototool or mask covering the portions that are to remain uncured is positioned, and the photoresist is cured using actinic radiation, such as that provided by a UV light. The portions that were covered by the phototool are uncured, and can be removed by the developing solution. More recently, direct laser imaging has been used to cure the applied photoresist. Using this method, the photoresist is applied to the substrate. A direct imager (e.g. MIVA 2050L Direct Imager) is used to image the portions of the photoresist in a specified pattern. The pattern is controlled by computer. Then, the non-imaged (non-exposed) areas are removed by developing with a dilute aqueous alkaline solution. By using direct imaging, the need for a physical mask (i.e. phototools) to cover the portions of the photoresist which will be removed during developing is eliminated. In both instances, the photoresist is generally then processed with a thermal curing step to harden the photoresist resin.

GB2032939 describes a UV-curable photoresist comprising the reaction product of a polyepoxide and an ethylenically unsaturated carboxylic acid, along with an inorganic filler and photoinitiators to enable initiation under the action of UV light.

GB2301826, EP1296188, EP1296189, EP1413926, EP1413926 and U.S. Pat. No. 5,009,982 all describe photocurable and thermosetting resist compositions comprising carboxyl-functional ethylenically unsaturated photocurable resins and polyepoxy resins. The resist composition, comprising the photocurable resin, photoinitiator and polyepoxide, along with other components such as solvent, filler, etc. after application and drying is exposed to UV radiation to cure the resist in a first step to produce the required image. The cured resist is then developed with an aqueous alkaline solution to remove the uncured resist, before being thermally cured to effect the epoxy-carboxylic acid thermoset reaction.

US2008/0096133 describes how photocurable and thermosetting resin compositions may be cured with a laser source in the 350 nm to 420 nm wavelength band. To achieve this, a specific blend of photoinitiators is used.

U.S. Pat. No. 9,458,284 describes similar photoresist compositions to those just mentioned. However, in the preparation of the carboxylic acid functional resin this is achieved by reacting residual epoxy groups remaining after the reaction with the ethylenically unsaturated carboxylic acid with the polyfunctional acid or anhydride.

U.S. Pat. No. 3,904,499 describes UV-curable compositions comprising thiols and ethylenically unsaturated resins and monomers. The preferred ethylenically unsaturated resin is one bearing allyl ethers. This composition cures via the thiol-ene process.

JP5485599 and JP2008211036 describe photoresist compositions comprising thiols. The thiol is included to reduce discolouration of white photoresist compositions and this is probably an artefact of the thiol's capacity as a reducing agent.

US2008/0096133, previously mentioned, describes the curing of photocurable and thermosetting resin compositions using lasers that have peak emittance in the 350 nm to 420 nm range.

WO2012023374, JP2013019945, CN102426413 disclose the use of lasers in the imaging of positive photoresists.

Of the identified relevant prior art the closest, JP5485599 and JP2008211036, describe the use of thiols to overcome a discolouration issue with white UV-curable photoresist compositions. U.S. Pat. No. 3,904,499 describes what is known to those skilled in the art as UV-curable ‘thiol-ene’ compositions.

Thus, there remains a need in the art for photoresists that are shelf-stable, can be cured with low-powered UV light, and exhibit good cure such as to provide well defined photoresist patterns.

### BRIEF SUMMARY OF THE INVENTION

The present invention provides photoresist compositions that are shelf-stable, enabling storage for long periods of time. The compositions of the present invention deliver the necessary cure required during the energy-curing stage process of preparing an electronic device, prior to the developing and thermoset stages. Thus, cured resists without defects such as matte surfaces, and potentially reduced undercut and overcut are possible.

In a particular aspect, the present invention provides an energy curable thermosetting resin composition comprising:
a) a carboxylic functional ethylenically unsaturated resin; and
b) an organosulphur compound;
   wherein the acid value of the composition is equal to or greater than 10 mg KOH/g; and
   wherein the composition is developable with an aqueous alkali solution, such that the uncured composition is removable by an aqueous alkali solution.

In certain embodiments, the photoresist composition is prepared as a 2-pack system, wherein:
a) Part A comprises a carboxylic functional ethylenically unsaturated resin and an organosulphur compound, wherein the acid value of Part A is equal to or greater than 10 mg KOH/g; and
b) Part B comprises a resin that is reactive with the carboxylic acid of Part A.

In another aspect, the present invention provides A method of preparing a printed circuit comprising:
a) providing a circuit board;
b) applying the composition of the invention on the circuit board;
c) curing exposed portions of the applied composition; and
d) developing the composition by removing the uncured portions of the composition with an aqueous alkaline solution.

In another aspect, the present invention provides a printed circuit board comprising the photoresist composition of the present invention.

The commercial advantages are clear. Compositions prepared according to the current invention will enable shelf-stable energy-curable negative photoresists to deliver the necessary cure required during the energy-curing stage of the process, prior to the developing and thermoset stages. Thus, cured resists without defects such as matt surfaces, and potentially reduced undercut and overcut are possible.

### DETAILED DESCRIPTION OF THE INVENTION

It is to be understood that the foregoing general description and the following detailed description are exemplary and explanatory only, and are not restrictive of any subject matter claimed.

Unless otherwise defined, all technical and scientific terms used herein have the same meaning as is commonly understood by one of skill in the art to which the inventions belong. All patents, patent applications, published applications and publications, websites and other published materials referred to throughout the entire disclosure herein, unless noted otherwise, are incorporated by reference in their entirety for any purpose.

The use of photoresists is generally described in the prior art, but the present invention is the first time that a stable photoresist comprising organosulphur compounds is disclosed. Although thiols are well known to be very effective in overcoming the effects of oxygen inhibition, as well as acting as highly effective co-initiators with type II photoinitiators such as thioxanthones, their use has been limited because they are highly prone to Michael reaction with acrylates. This is problematic for compositions comprising acrylates, to which thiols can readily react, causing increases in viscosity, and potentially gelation, of the composition. This is clearly a disadvantage with respect to the long-term shelf life of a composition comprising both acrylates and thiols. Consequently, there have not been photoresists where the thiol component is contained within the acrylate UV-curable resist.

A further disadvantage with the use of thiols is that they can also readily react with epoxies. Multifunctional epoxy resins are a common component of a hardener which enables a secondary thermal polymerization with the carboxyl functionality of the photocurable resist resin. This also limits the capability of supplying a shelf-stable photoresist composition comprising thiols with acrylate and epoxy (or oxetane) groups.

The present invention overcomes these disadvantages of using thiols with acrylate and epoxy resins. When the thiol component is contained within the carboxylic acid-functional UV-curable resist, the carboxylic acids groups stabilize the thiol. That is, the thiol is prevented from undergoing Michael addition with the (meth)acrylate content of the photoresist. There is a minimum acid value that is required to prevent the Michael addition reaction.

It should be understood that although thiols, including mercaptans, are preferred, other organosulphur compounds, such as thioethers, can be incorporated into the compositions of the present invention. Any organosulphur compound that can act as a proton donor in a free radical transfer process may be used in the compositions of the present invention.

A benefit of inclusion of thiol into the compositions of the present invention is that it helps to promote the UV-curing of the compositions, especially in the situations when low intensity UV-light sources, such as UV-LED lamps and UV (excimer) lasers, are used. Incorporating thiols into the compositions of the present invention helps to overcome the effects of oxygen inhibition. Oxygen inhibition can be problematic when curing of photoresists is carried out with low intensity UV-light sources. Where low intensity UV-light sources are used, the flux of radicals produced by the interaction of the incident UV light with any photoinitiators contained within a photoresist will be relatively low (compared with conventional UV-light sources such as medium pressure lamps and high power UV-LED lamps). Oxygen inhibition, whereby any reactive initiating or propagating radical may react with a molecule of oxygen to form a stable, inefficient peroxy radical, essentially attenuates the photopolymerization rate, and hence conversion of monomers to oligomers. The consequence of this is that poorly cured resists, especially of the uppermost surfaces (i.e. those exposed to atmospheric oxygen) may result, leading to deficiencies such as poor surface curing and poor resistance during the developing stage prior to any final thermal treatment. This latter issue can result in matting and marking/scuffing of the top surface of the cured photoresist. As well as improving surface cure, it has been surprisingly found that compositions prepared according to the present invention also have improved through-cure, resulting in improved final image definition.

The inventors have found that shelf-stable photoresist compositions, and in particular 2-pack photoresist compositions, can be produced by introducing the thiol into the carboxyl-functional curable resin component (Part A) of the composition of the present invention. It has further been discovered that stability is enhanced when the acid value of the carboxyl-functional curable resin component is preferably maintained above 10 mg KOH/g.

In the case of the 2-pack photoresist compositions, separating the thiol from the epoxy in the hardener component (Part B) of the 2-pack composition provides a further potential crosslinking reaction. During the second thermal curing stage, there can be further crosslinking between the epoxy hardener resin and thiol, as well as between the epoxy and carboxyl groups of the photopolymerizable resin. This is a feature that has not previously been appreciated. Indeed, because thiols are highly reactive toward epoxies, much more so than carboxylic acids and anhydrides, then it should be understood that the present invention not only includes the use of thiols to help overcome the effects of oxygen inhibition and to promote UV-cure, but also to act as a highly reactive crosslinking agent with the epoxy hardener during thermal cure.

A further aspect of the present invention, that has not been alluded to in the identified prior art, is the curing of the inventive compositions under low intensity UV light sources, such as those emitted by certain UV-LED lamps. For example, those lamps with peak irradiances of 12 W/cm² or lower, and UV-lasers, such as excimer lasers. Preferably the peak irradiance is 10 W/cm² or lower, or 8 W/cm² or lower. More preferably, the peak irradiance is 6 W/cm² or lower. This is an important factor of the current invention, which has not been disclosed in the identified prior art, and enables compositions of the current invention to achieve satisfactory cure after the UV-curing stage of the process, prior to the next stage involving development with a dilute aqueous alkaline solution to remove the uncured areas of the photocured image. The inventors have found that the incorporation of the organosulphur compound allows the blended photoresist, when cured under the action of a low power UV light source, such as that delivered by a MIVA 2050L Direct Imager, overcomes the issues resulting from poor cure, such as matting due to poor surface cure, and a reduction in overcut and undercut of the cured and developed photoresist. This is an important feature of the present invention as the direct imaging of photoresists achievable with such UV-light sources becomes increasingly more prevalent in the manufacture of electronic components, including the production of printed circuit boards. It should be understood that although there is a preference for the direct imaging of photoresist compositions, the present invention also includes the use of masks to produce the UV-cured image.

### Definitions

In this application, the use of the singular includes the plural unless specifically stated otherwise. As used herein, the singular forms “a,” “an” and “the” are intended to include the plural forms as well, unless the context clearly indicates otherwise.

In this application, the use of “or” means “and/or” unless stated otherwise.

As used herein, the terms “comprises” and/or “comprising” specify the presence of the stated features, integers, steps, operations, elements, and/or components, but do not preclude the presence or addition of one or more other features, integers, steps, operations, elements, components, and/or groups thereof. Furthermore, to the extent that the terms “includes,” “having,” “has,” “with,” “composed,” “comprised” or variants thereof are used in either the detailed description or the claims, such terms are intended to be inclusive in a manner similar to the term “comprising.”

As used herein, ranges and amounts can be expressed as “about” a particular value or range. “About” is intended to also include the exact amount. Hence “about 5 percent” means “about 5 percent” and also “5 percent.” “About” means within typical experimental error for the application or purpose intended.

As used herein, the terms “photoresist composition,” “photoresist,” “resist,” “composition,” and the like are used interchangeably, and refer to the compositions of the invention. The terms may be used to refer to only the composition comprising the carboxylic-functional resin and organosulphur compound (Part A) when it is used alone as a photoresist. Alternatively, the terms may be used to refer to the photoresist system comprising the Part A composition, and further comprising at least one additional composition (Part B) comprising a resin that may react with the carboxylic groups of Part A.

As used herein, the term “dam” means a cured photoresist line, such that there is a recessed space between photoresist lines in which a conductive material can be applied. As used in the industry, the term may also apply to a solder dam.

As used herein, the term “undercut” means that after developing, the bottom of the cured photoresist dam (line) is narrower than the top of the cured photoresist dam.

As used herein, the term “overcut” means that after developing, the top of the cured photoresist dam (line) is narrower than the bottom of the cured photoresist dam.

As used herein, the term “shelf-stable” means that the photoresist composition (e.g. containing an ethylenically unsaturated resin and an organosulphur compound) can be stored for long periods, up to 12 months, without significant changes in viscosity or gelling.

As used herein, a “carboxylic acid-functional,” “carboxyl functional”, and the like, resin is a resin or polymer having one or more reactive carboxyl (COOH) groups.

As used herein, use of the terms “acrylic,” “(meth)acrylic” or “methacrylic” all refer to both the acrylic and methacrylic compounds. The same is true for the acrylates and methacrylates.

As used herein, the term “organosulphur compound” refers to an organic compound that contains one or more sulphur groups.

As used herein, the term “thiol” refers to an organosulphur compound comprising one or more R—SH groups, where “R” denotes a carbon containing organic group.

As used herein, the term “mercaptan” refers to an organosulphur compound comprising one or more methanethiol (CH₃SH) groups.

As used herein, the term “thioether” refers to organosulphur compounds comprising one or more C—S—C bonds.

As used herein, the term “thiol-ene” reaction means a curing reaction between a thiol reactive group and an alkene to form an alkyl sulfide.

### Photoresist Composition

In one embodiment, the photoresist compositions are provided as 2-pack systems, with Part A (the “resist”) and Part B (the “hardener”). The invention further encompasses any photoresist composition comprising the blending of 2 or more packs and/or components.

In the case of the inventive 2-pack compositions, Part A comprises a carboxyl group containing resin which further comprises ethylenically unsaturated groups which are polymerizable via a free radical process, and an organosulphur compound, such as a thiol. There is no restriction on the nature of the thiol, and it may be monofunctional or multifunctional, although multifunctional thiols are preferred. It should be understood by those skilled in the art that where the term thiol is used, this also encompasses any material referred to as a mercaptan, including those materials, for example, produced by the reaction of polyhydric alcohols with mercaptoacetic and/or mercaptopropionic acids. Although not as effective, the invention also includes the use of thioethers.

The photosensitive carboxyl group containing resin of Part A can be prepared in a number of ways. For example, a typical approach would be the reaction of a polyfunctional epoxy compound with an unsaturated monocarboxylic acid, such as (meth)acrylic acid, and then reacting the hydroxyl groups of the resultant intermediate product with a polybasic acid or anhydride. It should be understood that there is no restriction on the nature of the carboxyl-functional photosensitive compound used in the compositions of the present invention. For example, US 2008/0096133 describes certain ways by which such resins may be produced, and is herein incorporated into the present invention. Part A may also optionally include any one or more of solvents, fillers, photoinitiators, monomers, oligomers, pigments, additives, etc.

Part A of the composition comprises a carboxyl group functional resin which further comprises ethylenically unsaturated groups which are polymerizable via a free radical process. Part A, although preferably used with Part B of an inventive 2-pack composition, may also be used by itself as a single-pack photoresist composition.

To enhance the shelf-stability of Part A, the acid value of Part A should preferably be 10 mg KOH/g or greater. Preferably the acid value of Part A is greater than 20 mg KOH/g, and more preferably greater than 25 mg KOH/g. For example, the acid value of the Part A composition is typically about 10 mg KOH/g to about 150 mg KOH/g. For example, the acid value of the Part A composition may be about 10 mg KOH/g to about 140 mg KOH/g; or about 10 mg KOH/g to about 130 mg KOH/g; or about 10 mg KOH/g to about 120 mg KOH/g; or about 10 mg KOH/g to about 110 mg KOH/g; or about 10 mg KOH/g to about 100 mg KOH/g; or about 10 mg KOH/g to about 90 mg KOH/g; or about 10 mg KOH/g to about 80 mg KOH/g; or about 10 mg KOH/g to about 70 mg KOH/g; or about 10 mg KOH/g to about 60 mg KOH/g; or about 10 mg KOH/g to about 50 mg KOH/g; or about 10 mg KOH/g to about 40 mg KOH/g; or about 10 mg KOH/g to about 30 mg KOH/g; or about 10 mg KOH/g to about 20 mg KOH/g; or about 20 mg KOH/g to about 150 mg KOH/g; or about 20 mg KOH/g to about 140 mg KOH/g; or about 20 mg KOH/g to about 130 mg KOH/g; or about 20 mg KOH/g to about 120 mg KOH/g; or about 20 mg KOH/g to about 110 mg KOH/g; or about 20 mg KOH/g to about 100 mg KOH/g; or about 20 mg KOH/g to about 90 mg KOH/g; or about 20 mg KOH/g to about 80 KOH/g; or about 20 mg KOH/g to about 70 mg KOH/g; or about 20 mg KOH/g to about 60 mg KOH/g; or about 20 mg KOH/g to about 50 mg KOH/g; or about 20 mg KOH/g to about 40 mg KOH/g; or about 20 mg KOH/g to about 30 mg KOH/g; or about 30 mg KOH/g to about 150 mg KOH/g; or about 30 mg KOH/g to about 140 mg KOH/g; or about 30 mg KOH/g to about 130 mg KOH/g; or about 30 mg KOH/g to about 120 mg KOH/g; or about 30 mg KOH/g to about 110 mg KOH/g; or about 30 mg KOH/g to about 100 mg KOH/g; or about 30 mg KOH/g to about 90 mg KOH/g; or about 30 mg KOH/g to about 80 mg KOH/g; or about 30 mg KOH/g to about 70 mg KOH/g; or about 30 mg KOH/g to about 60 mg KOH/g; or about 30 mg KOH/g to about 50 mg KOH/g; or about 30 mg KOH/g to about 40 mg KOH/g; or about 40 mg KOH/g to about 150 mg KOH/g; or about 40 mg KOH/g to about 140 mg KOH/g; or about 40 mg KOH/g to about 130 mg KOH/g; or about 40 mg KOH/g to about 120 mg KOH/g; or about 40 mg KOH/g to about 110 mg KOH/g; or about 40 mg KOH/g to about 100 mg KOH/g; or about 40 mg KOH/g to about 90 mg KOH/g; or about 40 mg KOH/g to about 80 mg KOH/g; or about 40 mg KOH/g to about 70 mg KOH/g; or about 40 mg KOH/g to about 60 mg KOH/g; or about 40 mg KOH/g to about 50 mg KOH/g; or about 50 mg KOH/g to about 150 mg KOH/g; or about 50 mg KOH/g to about 140 mg KOH/g; or about 50 mg KOH/g to about 130 mg KOH/g; or about 50 mg KOH/g to about 120 mg KOH/g; or about 50 mg KOH/g to about 110 mg KOH/g; or about 50 mg KOH/g to about 100 mg KOH/g; or about 50 mg KOH/g to about 90 mg KOH/g; or about 50 mg KOH/g to about 80 mg KOH/g; or about 50 mg KOH/g to about 70 mg KOH/g; or about 50 mg KOH/g to about 60 mg KOH/g; or about 60 mg KOH/g to about 150 mg KOH/g; or about 60 mg KOH/g to about 140 mg KOH/g; or about 60 mg KOH/g to about 130 mg KOH/g; or about 60 mg KOH/g to about 120 mg KOH/g; or about 60 mg KOH/g to about 110 mg KOH/g; or about 60 mg KOH/g to about 100 mg KOH/g; or about 60 mg KOH/g to about 90 mg KOH/g; or about 60 mg KOH/g to about 80 mg KOH/g; or about 60 mg KOH/g to about 70 mg KOH/g; or about 70 mg KOH/g to about 150 mg KOH/g; or about 70 mg KOH/g to about 140 mg KOH/g; or about 70 mg KOH/g to about 130 mg KOH/g; or about 70 mg KOH/g to about 120 mg KOH/g; or about 70 mg KOH/g to about 110 mg KOH/g; or about 70 mg KOH/g to about 100 mg KOH/g; or about 70 mg KOH/g to about 90 mg KOH/g; or about 70 mg KOH/g to about 80 mg KOH/g; or about 80 mg KOH/g to about 150 mg KOH/g; or about 80 mg KOH/g to about 140 mg KOH/g; or about 80 mg KOH/g to about 130 mg KOH/g; or about 80 mg KOH/g to about 120 mg KOH/g; or about 80 mg KOH/g to about 110 mg KOH/g; or about 80 mg KOH/g to about 100 mg KOH/g; or about 80 mg KOH/g to about 90 mg KOH/g; or about 90 mg KOH/g to about 150 mg KOH/g; or about 90 mg KOH/g to about 140 mg KOH/g; or about 90 mg KOH/g to about 130 mg KOH/g; or about 90 mg KOH/g to about 120 mg KOH/g; or about 90 mg KOH/g to about 110 mg KOH/g; or about 90 mg KOH/g to about 100 mg KOH/g; or about 100 mg KOH/g to about 150 mg KOH/g; or about 100 mg KOH/g to about 140 mg KOH/g; or about 100 mg KOH/g to about 130 mg KOH/g; or about 100 mg KOH/g to about 120 mg KOH/g; or about 100 mg KOH/g to about 110 mg KOH/g; or about 110 mg KOH/g to about 150 mg KOH/g; or about 110 mg KOH/g to about 140 mg KOH/g; or about 110 mg KOH/g to about 130 mg KOH/g; or about 110 mg KOH/g to about 120 mg KOH/g; or about 120 mg KOH/g to about 150 mg KOH/g; or about 120 mg KOH/g to about 140 mg KOH/g; or about 120 mg KOH/g to about 130 mg KOH/g; or about 130 mg KOH/g to about 150 mg KOH/g; or about 130 mg KOH/g to about 140 mg KOH/g; or about 140 mg KOH/g to about 150 mg KOH/g.

There is no restriction on the type of acid that provides the required acid value in stabilizing the organosulphur compound in the Part A compositions of the present invention, although carboxylic acids and anhydrides are preferred. Generally, carboxylic acid-functional ethylenically unsaturated resins are the usual material of choice in the preparation of photoresist compositions of the type described herein. Not only do these materials contribute the required acid value of the invention to stabilize the organosulphur compound, but are also able to take part in secondary reactions such as the thermal crosslinking with epoxy resins.

Other carboxylic acids that may be used include, but are not limited to, formic acid, acetic acid, propionic acid, oxalic acid, citric acid, poly(acrylic acid), poly(methacrylic acid), and copolymers of acrylic acid and copolymers of methacrylic acid. Where such non-ethylenically functional carboxylic acids and anhydrides are used, it is preferred that they are polyfunctional with respect to the number of carboxylic acid moieties per molecule.

The present invention also covers instances where the stabilizing acid functionality is provided by acidic material other than carboxylic acid. Organic acids are preferred, and, as such, organosulphonic and organophosphoric acids may be used. Inorganic acids may also be used, although not preferred, and include, but are not limited to, sulphuric, hydrochloric, nitric, phosphoric, boric, and perchloric acids.

Any carboxylic functional resin may be used in the preparation of Part A, but those bearing ethylenically unsaturated groups are most preferred, and especially those resins where the etheylenically unsaturated groups are (meth)acrylate, and most especially where the ethylenically unsaturated groups are acrylate. There is no restriction on the type of carboxylic-functional, (meth)acrylated resin used, but by way of example, such resins may be produced by the reaction of polyepoxide resin with (meth)acrylic acid to produce a hydroxyl-functional (meth)acrylated intermediate. This intermediate may then be reacted with a polyfunctional carboxylic acid or anhydride, such as terephthalic anhydride, to form the desired carboxylic-functional ethylenically unsaturated resin. There are a number of other approaches to the preparation of such carboxylic ethylenically unsaturated resins, and the processes disclosed by EP 1296188 and U.S. Pat. No. 9,458,284 are included herein by reference.

Acid functional acrylates may also be used in the preparation of Part A. It is also possible to prepare Part A of the composition by blending a carboxylic-functional resin with any blend of suitable ethylenically unsaturated resins, including those that are carboxylic-functional themselves, or essentially free of any carboxylic acid or anhydride.

Typically, the Part A composition of the invention comprises about 10% (w/w) to about 50% (w/w) carboxylic-functional resin, based on the total weight of the Part A composition. In one embodiment, the carboxylic-functional resin may be present in the Part A composition in an amount of about 35% (w/w). For example, the carboxylic-functional resin may be present in the Part A composition in an amount of about 10% (w/w) to about 45% (w/w); or about 10% to about 40%; or about 10% to about 35%; or about 10% to about 30%; or about 10% to about 25%; or about 10% to about 20%; or about 10% to about 15%; or about 15% to about 50%; or about 15% to about 45%; or about 15% to about 40%; or about 15% to about 35%; or about 15% to about 30%; or about 15% to about 25%; or about 15% to about 20%; or about 20% to about 50%; or about 20% to about 45%; or about 20% to about 40%; or about 20% to about 35%; or about 20% to about 30%; or about 20% to about 25%; or about 25% to about 50%; or about 25% to about 45%; or about 25% to about 40%; or about 25% to about 35%; or about 25% to about 30%; or about 30% to about 50%; or about 30% to about 45%; or about 30% to about 40%; or about 30% to about 35%; or about 35% to about 50%; or about 35% to about 45%; or about 35% to about 40%; or about 40% to about 50%; or about 40% to about 45%; or about 45% to about 50%.

Any organosulphur compound that can act as a proton donor in a free radical transfer process may be used in the compositions of the present invention. These include thiols, mercaptans, and thioethers. Suitable thiols and thioethers include, but are not limited to: tri(3-mercaptopropionate) (TMPP); thioglycolic Acid (TGA); 2-ethylhexyl mercaptoacetate; iso-octylmercaptoacetate; glyceryl mercaptoacetate; glycol dimercaptoacetate; pentaerythritol tetramercaptoacetate; 3-mercaptopropionic acid; butyl-3-mercaptopropionate; 2-Ethylhexyl 3-mercaptopropionate; glycol di(3-mercaptopropionate); trimethylolpropane tri(3-mercaptopropionate) (TMPMP); pentaerythritol tetra(3-mercaptopropionate) (PETMP); dipentaerythritol hexa(3-mercaptopropionate) (DiPETMP); ethoxylated-trimethylolpropan tri(3-mercaptopropionate); combinations thereof; and the like. Multifunctional thiols, that is, bearing two or more thiol groups per molecule, are preferred.

Typically, the Part A composition comprises greater than about 0.5% (w/w) of organosulphur compound, based on the total weight of the Part A composition. Preferably, Part A comprises greater than 1.0% (w/w) organosulphur compound, and more preferably greater than 2.5% (w/w) organosulphur compound. The Part A composition typically comprises about 0.5% (w/w) to about 20% (w/w) organosulphur compound. For example the Part A composition may comprise the organosulphur compound in an amount of about 0.5% (w/w) to about 15% (w/w); or about 0.5% to about 10%; or about 0.5% to about 5%; or about 0.5% to about 1%; or about 1% to about 20%; or about 1% to about 15%; or about 1% to about 10%; or about 1% to about 5%; or about 5% to about 20%; or about 5% to about 15%; or about 5% to about 10%; or about 10% to about 20%; or about 10% to about 15%; or about 15% to about 20%.

It should be noted that Part A, without blending with Part B, may be used as a photoresist in its own right (i.e. as a single pack). The full resistance required of the final resist is achieved via the thermally activated Michael addition between residual acrylate remaining after the UV curing steps and the multifunctional organosulphur, preferably thiol, compounds contained in Part A.

Part B of the present inventive composition comprises a resin bearing a plurality of groups which are able to react with the carboxylic acid contained in Part A. Polyfunctional epoxy resins are especially preferred.

Part B of the inventive 2-pack compositions may comprise any blend of reactive hardeners which crosslink with the carboxyl groups of the photosensitive resin contained within Part A. Although polyfunctional epoxy resins are preferred, there is no restriction on the nature of the hardener other than it is able to react with carboxylic acid. As well as polyepoxides, the hardener includes, but is not limited to, for example, polyoxetanes, aminoresins, blocked isocyanates, polyoxazolines, or polycarbodiimides. As well as the hardener resin, Part B of the inventive 2-pack composition may also optionally include any one or more of solvents, fillers, photoinitiators, monomers, oligomers, pigments, additives, etc.

The Part B composition of the present invention comprises a resin that may react with the carboxylic groups contained within Part A. Although polyfunctional epoxy resins are preferred, there is no restriction on the nature of the hardener other than that it is able to react with carboxylic acid. As well as polyepoxides, the hardener may also be a polyoxetane, an aminoresin, a blocked isocyanate, polyoxazoline, or polycarbodiimide. Where polyfunctioinal epoxy resins are used in the preparation of Part B, they can include, but are not limited to: diglycidyl ethers of bisphenol A; diglycidyl ethers of bisphenol F; diglycidyl ethers of bisphenol S; phenol novolac epoxy resins; cresol novolac epoxy resins; aliphatic glycidyl ethers of any polyfunctional alcohol, such as neopentyl glycol diglycidyl ether, cyclohexanedimethanol diglycidyl ether, trimethylolethane triglycidyl ether, polypropylene glycol diglycidyl ether, trimethylolpropane triglycidyl ether; hydrogenated bisphenol A type epoxy resin; a bromination bisphenol A type epoxy resin; N-glycidyl type epoxy resin; Novolac type epoxy resin of bisphenol A; a biphenol type epoxy resin; a chelate type epoxy resin; a glyoxal type epoxy resin; an amino group content epoxy resin; a rubber modified epoxy resin; a dicyclopentadiene phenolic type epoxy resin; diglycidyl phthalate resin; heterocyclic epoxy resin; silicone modified epoxy resin; epsilon-caprolactone modified epoxy resin; combinations thereof; and the like.

A non-exhaustive list of commercially available epoxy-functional resins that may be used include, but is not restricted to: jER™828, jER834, jER1001, jER1004 (all are the Mitsubishi Chemical make); Epiclon 840, Epiclon 850, Epiclon 1050, Epiclon 2055 (all are the products made by DIC); EPO TOTO (registered trademark); YD-011, YD-013, YD-127, YD-128 (all are the Nippon Steel Chemical Co., Ltd. make); D.E.R.317, D.E.R.331, D.E.R.661, D.E.R.664 (all are the Dow Chemical Co. make, Araldite 6071, Araldite 6084, Araldite GY250, Araldite GY260 (all are the BASFJapan make); SUMIEPOKISHI ESA-011, ESA-014, ELA-115, ELA-128 (all are the Sumitomo Chemical Co., Ltd. make); a bisphenol A type epoxy resin; jERYL903 (made by Mitsubishi Chemical); E.R.330, A.E.R.331, A.E.R.661, and A.E.R.664 (all are the Asahi Chemical Industry Co., Ltd. make); Epiclon 152, Epiclon 165 (all are the products made by DIC); EPO TOTO YDB-400, YDB-500 (all are the Nippon Steel Chemical Co., Ltd. make); D.E.R.542 (made by the Dow Chemical Co.); Araldite 8011 (made by BASF Japan); SUMIEPOKISHI ESB-400, ESB-700 (all are the Sumitomo Chemical Co., Ltd. make); a bromine-ized epoxy resin; jER152, such as E.R.711 and A.E.R.714 (all are the Asahi Chemical Industry Co., Ltd. make); jER154 (Mitsubishi Chemical make); D.E.N.431, D.E.N.438 (all are the Dow Chemical Co. make); Epiclon N-730, Epiclon N-770, Epiclon N-865 (all are the products made by DIC); EPO TOTO YDCN-701, YDCN-704 (all are the Nippon Steel Chemical Co., Ltd. make); Araldite ECN1235, Araldite ECN1273, Araldite ECN1299, Araldite XPY307 (all are the BASF Japan make); EPPN-201, EOCN1025, EOCN-1020, EOCN-1045, RE-306 (all are the Nippon Kayaku Co., Ltd. make); SUMIEPOKISHI ESCN-195X, ESCN-220 (all are the Sumitomo Chemical Co., Ltd. make); A.E.R.ECN-235; novolak type epoxy resin; ECN-299 (Asahi Chemical Industry Co., Ltd. make); Epiclon 830 (made by DIC); jER807 (made by Mitsubishi Chemical); EPO TOTO YDF-170, YDF-175, YDF-2004 (all are the Nippon Steel Chemical Co., Ltd. make); bisphenol F type epoxy resin; Araldite XPY306 (made by BASF Japan); hydrogenation bisphenol A type epoxy resin; jER604 (made by Mitsubishi Chemical); EPO TOTO ST-2004, ST-2007, and ST-3000 (all are the Nippon Steel Chemical Co., Ltd. make); EPO TOTO YH-434 (made by Nippon Steel Chemical Co., Ltd.); Araldite MY720 (made by BASF Japan); glycidyl amine-type-epoxy-resin; SUMIEPOKISHI ELM-120 (made by Sumitomo Chemical Co., Ltd.); hydantoin type epoxy resin; Araldite CY-350 (made by BASF Japan); SEROKI Side™ 2021 (made by Daicel Chemical Industries, Ltd.); cycloaliphatic-epoxy-resin; YL-933 (made by Mitsubishi Chemical); Araldite CY175 and CY179 (all are the BASF Japan make); T.E.N., EPPN™501, trihydroxy phenylmethane type epoxy resins, such as EPPN-502 (all are the Nippon Kayaku Co., Ltd. make); A BIKISHIRE Norian type or biphenol type epoxy resins, such as YL-6056, YX-4000, and YL-6121 (all are the Mitsubishi Chemical make); EBPS-200 (made by Nippon Kayaku Co., Ltd.); EPX-30 (made by ADEKA); bisphenol A novolak type epoxy resin; bisphenol smooth S form epoxy resin; jER157S (made by Mitsubishi Chemical); EXA-1514 (made by DIC); jERYL-931 (made by Mitsubishi Chemical); Tetra FENI roll ethane type epoxy resins; Araldite 163 (made by BASF Japan); Araldite PT810 (made by BASF Japan); TEPIC (Nissan Chemical Industries, Ltd.); heterocyclic epoxy resin; Blemmer™ (made by NOF Corporation); diglycidyl phthalate resin; DGT (Nippon Oil & Fats Co.); tetraglycidyl ether of tetraphenol ethane resin; ZX-1063 (made by Nippon Steel Chemical Co., Ltd.); ESN-190 and ESN-360 (all are the Nippon Steel Chemical Co., Ltd. make); naphthalene group content epoxy resin; HP-7200, HP-4032, EXA-4750, and EXA-4700 (made by DIC); the epoxy resin which has dicyclopentadiene skeletons; HP-7200H (made by DIC); CP-50S, glycidyl methacrylate copolymerization system epoxy resin; CP-50M (Nippon Oil & Fats Co.); the copolymerization epoxy resin of cyclohexylmaleimide and glycidyl methacrylate; the polybutadiene rubber derivative of epoxy denaturation; combinations thereof; and the like.

It should be appreciated that any blend of any epoxy resin may be used. Furthermore, it should be appreciated that any blend of epoxy resins may be used in the preparation of the carboxylic-functional ethylenically unsaturated photoresist resin. Furthermore, it should be appreciated that any polycarboxylic acid or anhydride may be used in the preparation of the carboxylic-functional resist including but not restricted to; phthallic anhydride, tetrahydrophthallic anhydride, trimellitic anhydride, terephthallic acid, terephthallic anhydride, maleic anhydride, succinic anhydride, succinic acid, etc.

Parts A and B of the inventive compositions may optionally comprise other materials typically found in photoresists. These include, but are not limited to, monomers, oligomers, photoinitiators, solvent, pigments, fillers, other additives, etc.

Examples of suitable monofunctional ethylenically unsaturated monomers that may be used include, but are not limited to, the following: isobutyl acrylate; cyclohexyl acrylate; iso-octyl acrylate; n-octyl acrylate; isodecyl acrylate; iso-nonyl acrylate; octyl/decyl acrylate; lauryl acrylate; 2-propyl heptyl acrylate; tridecyl acrylate; hexadecyl acrylate; stearyl acrylate; iso-stearyl acrylate; behenyl acrylate; tetrahydrofurfuryl acrylate; 4-t.butyl cyclohexyl acrylate; 3,3,5-trimethylcyclohexane acrylate; isobornyl acrylate; dicyclopentyl acrylate; dihydrodicyclopentadienyl acrylate; dicyclopentenyloxyethyl acrylate; dicyclopentanyl acrylate; benzyl acrylate; phenoxyethyl acrylate; 2-hydroxy-3-phenoxypropyl acrylate; alkoxylated nonylphenol acrylate; cumyl phenoxyethyl acrylate; cyclic trimethylolpropane formal acrylate; 2(2-ethoxyethoxy) ethyl acrylate; polyethylene glycol monoacrylate; polypropylene glycol monoacrylate; caprolactone acrylate; ethoxylated methoxy polyethylene glycol acrylate; methoxy triethylene glycol acrylate; tripropyleneglycol monomethyl ether acrylate; diethylenglycol butyl ether acrylate; alkoxylated tetrahydrofurfuryl acrylate; ethoxylated ethyl hexyl acrylate; alkoxylated phenol acrylate; ethoxylated phenol acrylate; ethoxylated nonyl phenol acrylate; propoxylated nonyl phenol acylate; polyethylene glycol o-phenyl phenyl ether acrylate; ethoxylated p-cumyl phenol acrylate; ethoxylated nonyl phenol acrylate; alkoxylated lauryl acrylate; ethoxylated tristyrylphenol acrylate; N-(acryloyloxyethyl)hexahydrophthalimide; N-butyl 1,2 (acryloyloxy) ethyl carbamate; acryloyl oxyethyl hydrogen succinate; octoxypolyethylene glycol acrylate; octafluoropentyl acrylate; 2-isocyanato ethyl acrylate; acetoacetoxy ethyl acrylate; 2-methoxyethyl acrylate; dimethyl aminoethyl acrylate; 2-carboxyethyl acrylate; 4-hydroxy butyl acrylate; combinations thereof; and the like. In these materials the term ethoxylated refers to chain extended compounds through the use of ethyleneoxide, propoxylated refers to chain extended compounds through the use of propylene oxide, and alkoxylated refers to chain extended compound using either or both ethyleneoxide or propylene oxide. Equivalent methacrylate compounds are also capable of being used, although those skilled in the art will appreciate that the methacrylate compounds have lower reactivity than their equivalent acrylate counterparts.

Examples of suitable multifunctional ethylenically unsaturated monomers include, but are not limited to, the following: 1,3-butylene glycol diacrylate; 1,4-butanediol diacrylate; neopentyl glycol diacrylate; ethoxylated neopentyl glycol diacrylate; propoxylated neopentyl glycol diacrylate; 2-methyl-1,3-propanediyl ethoxy acrylate; 2-methyl-1,3-propanediol diacrylate; ethoxylated 2-methyl-1,3-propanediol diacrylate; 3 methyl 1,5-pentanediol diacrylate; 2-butyl-2-ethyl-1,3-propanediol diacrylate; 1,6-hexanediol diacrylate; alkoxylated hexanediol diacrylate; ethoxylated hexanediol diacrylate; propoxylated hexanediol diacrylate; 1,9-nonanediol diacrylate; 1,10 decanediol diacrylate; ethoxylated hexanediol diacrylate; alkoxylated hexanediol diacrylate; diethyleneglycol diacrylate; triethylene glycol diacrylate; tetraethylene glycol diacrylate; polyethylene glycol diacrylate; propoxylated ethylene glycol diacrylate; dipropylene glycol diacrylate; tripropyleneglycol diacrylate; polypropylene glycol diacrylate; poly (tetramethylene glycol) diacrylate; cyclohexane dimethanol diacrylate; ethoxylated cyclohexane dimethanol diacrylate; alkoxylated cyclohexane dimethanol diacrylate; polybutadiene diacrylate; hydroxypivalyl hydroxypivalate diacrylate; tricyclodecanedimethanol diacrylate; 1,4-butanediylbis[oxy(2-hydroxy-3,1-propanediyl)]diacrylate; ethoxylated bisphenol A diacrylate; propoxylated bisphenol A diacrylate; propoxylated ethoxylated bisphenol A diacrylate; ethoxylated bisphenol F diacrylate; 2-(2-Vinyloxyethoxy)ethyl acrylate; dioxane glycol diacrylate; ethoxylated glycerol triacrylate; glycerol propoxylate triacrylate; pentaerythritol triacrylate; trimethylolpropane triacrylate; caprolactone modified trimethylol propane triacrylate; ethoxylated trimethylolpropane triacrylate; propoxylated trimethylol propane triacrylate; tris (2-hydroxy ethyl) isocyanurate triacrylate; ε-caprolactone modified tris (2-hydroxy ethyl) isocyanurate triacrylate; melamine acrylate oligomer; pentaerythritol tetraacrylate; ethoxylated pentaerythritol tetraacrylate; di-trimethylolpropane tetra acrylate; dipentaerythritol pentaacrylate; dipentaerythritol hexaacrylate; ethoxylated dipentaerythritol hexaacrylate; combinations thereof; and the like. In these materials the term ethoxylated refers to chain extended compounds through the use of ethyleneoxide, propoxylated refers to chain extended compounds through the use of propylene oxide, and alkoxylated refers to chain extended compound using either or both ethyleneoxide or propylene oxide. Equivalent methacrylate compounds are also capable of being used, although those skilled in the art will appreciate that the methacrylate compounds have lower reactivity than their equivalent acrylate counterparts.

Examples of monomers comprising free-radically polymerisable groups other than acrylate include N-vinyl amides and vinyl ethers. Examples of N-vinyl amides and vinyl ethers include but are not limited to N-vinylcaprolactam (NVC), N-vinyl pyrollidone (NVP), diacetone acrylamide, N-vinyl oxazolidinone or N-vinyl methoxazolidinone, N-vinyl carbazole, N-acryloxyoxyethylcyclohexanedicarboximide, N-vinyl imidazole, N-vinyl-N-methylacetamide (VIMA) or acryloyl morpholine (ACMO); vinyl ethers such as 2-(2-vinyloxyethoxy)ethyl(meth)acrylate (VEEA, VEEM), diethylene glycol divinyl ether (DVE2), triethylene glycol divinyl ether (DVE3), ethyl vinyl ether, n-butyl vinyl ether, iso-butyl vinyl ether, tert-butyl vinyl ether, cyclohexyl vinyl ether (CHVE), 2-ethylhexyl vinyl ether (EHVE),dodecyl vinyl ether (DDVE), octadecyl vinyl ether (ODVE), 1-2-butanediol divinyl ether (BDDVE), 1-4, cyclohexanedimethanol divinylether (CHDM-di), hydroxybutyl vinylether (HBVE), 1-4-cyclohexanedimethanolmono vinylether (CHDM-mono), 1,2,4-trivinylcyclohexane (TVCH), vinylphosphonic acid dimethylester (VPA) or vinylphosphonic acid dimethyl ester (VPADME), combinations thereof, and the like.

As well as free radically-polymerisable monomers the inventive polymeric aminoacrylates may also be compounded with any concentration and type of free-radically polymerisable oligomer, including but not restricted to polyurethane acrylates, polyester acrylates, polyether acrylates and epoxy acrylates.

When present, monomers and oligomers are generally present in an amount of about 0.5% (w/w) to about 15% (w/w), based upon the total weight of the Part A or Part B composition in which they are contained. In one embodiment, the monomers and oligomers are present in an amount of about 6% (w/w). For example, the monomers and oligomers may be present in an amount of about 0.5% (w/w) to about 10% (w/w); or about 0.5% to about 5%; or about 0.5% to about 1%; or about 1% to about 15%; or about 1% to about 10% or about 1% to about 5%; or about 5% to about 15%; or about 5% to about 10%; or about 10% to about 15%.

Parts A and B of the inventive compositions may also contain one or more photoinitiators. Suitable photoinitiators include, but are not limited to α-hydroxyketones, acylphosphine oxides, α-aminoketones, thioxanthones, benzophenones, phenyl glyoxylates, oxime esters, acetophenones, benzil compounds and derivatives thereof, fluorenones, anthraquinones, combinations thereof, and the like.

Suitable α-hydroxyketone photoinitiators include, but are not limited to: 1-hydroxy-cyclohexyl-phenyl-ketone; 2-hydroxy-2-methyl-1-phenyl-1-propanone; 2-hydroxy-2-methyl-4′-tert-butyl-propiophenone; 2-hydroxy-4′-(2-hydroxyethoxy)-2-methyl-propiophenone; 2-hydroxy-4′-(2-hydroxypropoxy)-2-methyl-propiophenone; oligo 2-hydroxy-2-methyl-1-[4-(1-methyl-vinyl)phenyl]propanone; bis[4-(2-hydroxy-2-methylpropionyl)phenyl]methane; 2-Hydroxy-1-[1-[4-(2-hydroxy-2-methylpropanoyl)phenyl]-1,3,3-trimethylindan-5-yl]-2-methylpropan-1-one and 2-Hydroxy-1-[4-[4-(2-hydroxy-2-methylpropanoyl)phenoxy]phenyl]-2-methylpropan-1-one; combinations thereof; and the like.

Suitable acylphosphine oxide photoinitiators include, but are not limited to: 2,4,6-trimethylbenzoyl-diphenylphosphine oxide; ethyl (2,4,6-trimethylbenzoyl)phenyl phosphinate; and bis-(2,4,6-trimethylbenzoyl)-phenylphosphine oxide; combinations thereof; and the like.

Suitable α-aminoketone photoinitiators include, but are not limited to: 2-methyl-1-[4-methylthio)phenyl]-2-morpholinopropan-1-one; 2-benzyl-2-dimethylamino-1-(4-morpholinophenyl)-butan-1-one; and 2-dimethylamino-2-(4-methyl-benzyl)-1-(4-morpholin-4-yl-phenyl)-butan-1-one; combinations thereof; and the like.

Suitable thioxanthone photoinitiators include, but are not limited to: 2-4-diethylthioxanthone, isopropylthioxanthone, 2-chlorothioxanthone, and 1-chloro-4-propoxythioxanthone; combinations thereof; and the like.

Suitable benzophenone photoinitiators include, but are not limited to: benzophenone, 4-phenylbenzophenone, and 4-methylbenzophenone; methyl-2-benzoylbenzoate; 4-benzoyl-4-methyldiphenyl sulphide; 4-hydroxybenzophenone; 2,4,6-trimethyl benzophenone, 4,4-bis(diethylamino)benzophenone; benzophenone-2-carboxy(tetraethoxy)acrylate; 4-hydroxybenzophenone laurate and 1-[-4-[benzoylphenylsulpho]phenyl]-2-methyl-2-(4-methylphenylsulphonyl)propan-1-one; combinations thereof; and the like.

Suitable phenylglyoxylate photoinitiators include, but are not limited to: phenyl glyoxylic acid methyl ester; oxy-phenyl-acetic acid 2-[hydroxyl-ethoxy]-ethyl ester, or oxy-phenyl-acetic acid 2-[2-oxo-2-phenyl-acetoxy-ethoxy]-ethyl ester; combinations thereof, and like.

Suitable oxime ester photoinitiators include, but are not limited to: 1-phenyl-1,2-propanedione-2-(O-ethoxycarbonyl)oxime; [1-(4-phenylsulfanylbenzoyl)heptylideneamino]benzoate, or [1-[9-ethyl-6-(2-methylbenzoyl)carbazol-3-yl]-ethylideneamino]acetate; combinations thereof; and the like.

Examples of other suitable photoinitiators include diethoxy acetophenone; benzil; benzil dimethyl ketal; titanocen radical initiators such as titanium-bis(η5-2,4-cyclopentadien-1-yl)-bis-[2,6-difluoro-3-(1H-pyrrol-1-yl)phenyl]; 9-fluorenone; camphorquinone; 2-ethyl anthraquinone; combinations thereof; and the like.

Polymeric photoinitiators and sensitisers are also suitable, including, for example: polymeric aminobenzoates (GENOPOL AB-1 or AB-2 from RAHN, Omnipol ASA from IGM or Speedcure 7040 from Lambson); polymeric benzophenone derivatives (GENOPOL BP-1 or BP-2 from RAHN, Omnipol BP, Omnipol BP2702 or Omnipol 682 from IGM or Speedcure 7005 from Lambson); polymeric thioxanthone derivatives (GENOPOL TX-1 or TX-2 from RAHN, Omnipol TX from IGM or Speedcure 7010 from Lambson); polymeric aminoalkylphenones such as Omnipol 910 from IGM; polymeric benzoyl formate esters such as Omnipol 2712 from IGM; and the polymeric sensitiser Omnipol SZ from IGM.

An amine synergist may also be optionally included in the formulation. Suitable examples include, but are not limited to, the following: Aromatic amines such as; 2-(dimethylamino)ethylbenzoate; N-phenyl glycine; benzoic acid, 4-(dimethylamino)-, 1,1′-[(methylimino)di-2,1-ethanediyl] ester; and simple alkyl esters of 4-(N,N-dimethylamino)benzoic acid, with ethyl, amyl, 2-butoxyethyl and 2-ethylhexyl esters being particularly preferred; other positional isomers of N,N-dimethylamino)benzoic acid esters are also suitable.

Aliphatic amines such as N-methyldiethanolamine, triethanolamine and tri-isopropanolamine may also be included.

Aminoacrylates and amine modified polyether acrylates can be included, such as EBECRYL 80, EBECRYL 81, EBECRYL 83, EBECRYL 85, EBECRYL 880, EBECRYL LEO 10551, EBECRYL LEO 10552, EBECRYL LEO 10553, EBECRYL 7100, EBECRYL P115 and EBECRYL P116 available from ALLNEX; CN501, CN550, CN UVA421, CN3705, CN3715, CN3755, CN381 and CN386, all available from Sartomer; GENOMER 5142, GENOMER 5161, GENOMER 5271 and GENOMER 5275 from RAHN; PHOTOMER 4771, PHOTOMER 4967, PHOTOMER 5006, PHOTOMER 4775, PHOTOMER 5662, PHOTOMER 5850, PHOTOMER 5930, and PHOTOMER 4250 all available from IGM, LAROMER LR8996, LAROMER LR8869, LAROMER LR8889, LAROMER LR8997, LAROMER PO 83F, LAROMER PO 84F, LAROMER PO 94F, LAROMER PO 9067, LAROMER PO 9103, LAROMER PO 9106 and LAROMER P077F, all available from BASF; AGISYN 701, AGISYN 702, AGISYN 703, NeoRad P-81 and NeoRad P-85 ex DSM-AGI.

Where photoinitiators are included in compositions according to the invention it is preferred that they should be able to initiate photopolymerisation when exposed to UV light in the 300 to 420 nm wavelength band.

When present, the one or more photoinitiators may be present in an amount of about 0.1% (w/w) to about 10% (w/w), based upon the total weight of the Part A or Part B composition in which they are contained. In one embodiment, the photoinitiators are present in an amount of about 5% (w/w). For example, the photoinitiators may be present in an amount of about 0.1% (w/w) to about 10% (w/w); or about 0.1% to about 5%; or about 0.1% to about 1%; or about 0.1% to about 0.5%; or about 0.5% to about 10%; or about 0.5% to about 5%; or about 0.5% to about 1%; or about 1% to about 10%; or about 1% to about 5%; or about 5% to about 10%.

Where the compositions of the invention require colorants, suitable colorants include, but are not limited to organic or inorganic pigments and dyes. The dyes include but are not limited to azo dyes, anthraquinone dyes, xanthene dyes, azine dyes, combinations thereof and the like. Organic pigments may be one pigment or a combination of pigments, such as for instance Pigment Yellow Numbers 12, 13, 14, 17, 74, 83, 114, 126, 127, 174, 188; Pigment Red Numbers 2, 22, 23, 48:1, 48:2, 52, 52:1, 53, 57:1, 112, 122, 166, 170, 184, 202, 266, 269; Pigment Orange Numbers 5, 16, 34, 36; Pigment Blue Numbers 15, 15:3, 15:4; Pigment Violet Numbers 3, 23, 27; and/or Pigment Green Number 7. Inorganic pigments may be one of the following non-limiting pigments: iron oxides, titanium dioxides, chromium oxides, ferric ammonium ferrocyanides, ferric oxide blacks, Pigment Black Number 7 and/or Pigment White Numbers 6 and 7. Other organic and inorganic pigments and dyes can also be employed, as well as combinations that achieve the colors desired.

When present, the one or more colorants may be present in an amount of about 0.2% (w/w) to about 2% (w/w), based upon the total weight of the Part A or Part B composition in which they are contained. In one embodiment, the colorants are present in an amount of about 1% (w/w). For example, the colorants may be present in an amount of about 0.2% to about 1.5%; or about 0.2% to about 1%; or about 0.2% to about 0.5%; or about 0.5% to about 2%; or about 0.5% to about 1.5%; or about 0.5% to about 1%; or about 1% to about 2%; or about 1% to about 1.5%; or about 1.5% to about 2%.

Solvents may be used to reduce the viscosity of Parts A and B of the inventive compositions to the required application viscosity. The solvent is then removed in an evaporation stage prior to further processing. Suitable solvents include, but are not restricted to: ketone; toluene; methyl ethyl ketone; cyclohexanone; aromatic hydrocarbon, such as xylene and tetramethyl benzene; Cellosolve; Methyl cellosolve; butyl cellosolve; carbitol; methylcarbitol; butylcarbitol; propylene glycol monomethyl ether; propylene glycol monoethyl ether; glycol ether, such as dipropylene glycol diethylether and triethylene glycol monoethyl ether; ethyl acetate; butyl acetate; a cellosolve acetate; butyl-cellosolve acetate; carbitol acetate; butylcarbitol acetate; propylene-glycol-monomethyl-ether acetate; acetate ester, such as dipropylene-glycol-monomethyl-ether acetate; ethanol; alcohols, such as propanol, ethylene glycol, and propylene glycol; octane; aliphatic hydrocarbon, such as Deccan; petroleum solvents, such as petroleum ether, petroleum naphtha, hydrogenation petroleum naphtha, and solvent naphtha; combinations thereof; and the like.

In certain embodiments, the compositions contain no solvents. When present, the one or more solvents may be present in an amount of about 0.5% (w/w) to about 70% (w/w), based upon the total weight of the Part A or Part B composition in which they are contained. Adding a solvent may include thinning the ink system for low viscosity applications including but not limited to curtain coating and spray. In one embodiment, solvents are present in an amount of about 10% (w/w), based upon the total weight of the Part A or Part B composition in which they are contained. For example, the solvents may be present in an amount of about 0.5% (w/w) to about 60% (w/w); or about 0.5% to about 50%; or about 0.5% about 40%; or about 0.5% to about 30%; or about 0.5% to about 20%; or about 0.5% to about 10%; or about 0.5% to about 5%; or about 0.5% to about 1%; or about 1% to about 70%; or about 1% to about 60%; or about 1% to about 50%; or about 1% to about 40%; or about 1% to about 30%; or about 1% to about 20%; or about 1% to about 10%; or about 1% to about 5%; or about 5% to about 70%; or about 5% to about 60%; or about 5% to about 50%; or about 5% to about 40%; or about 5% to about 30%; or about 5% to about 20%; or about 5% to about 10%; or about 10% to about 70%; or about 10% to about 60%; or about 10% to about 50%; or about 10% to about 40%; or about 10% to about 30%; or about 10% to about 20%; or about 20% to about 70%; or about 20% to about 60%; or about 20% to about 50%; or about 20% to about 40%; or about 20% to about 30%; or about 30% to about 70%; or about 30% to about 60%; or about 30% to about 50%; or about 30% to about 40%; or about 40% to about 70%; or about 40% to about 60%; or about 40% to about 50%; or about 50% to about 70%; or about 50% to about 60%; or about 60% to about 70%.

It is common to include a catalyst into photoresist compositions to accelerate the thermoset reaction. Catalysts which may be used include, but are not restricted to: imidazole; 2-methylimidazole; 2-ethylimidazole; 2-ethyl-4-methylimidazole; 2-phenylimidazole; 4-phenylimidazole; 1-cyanoethyl-2-phenylimidazole; imidazole derivatives, such as 1-(2-cyanoethyl)-2-ethyl-4-methyl imidazole; dicyandiamide; benzyldimethylamine, 4-(dimethylamino)-N,N-dimethylbenzylamine; hydrazine compounds; amine compounds, such as 4-methoxy-N,N-dimethylbenzylamine and 4-methyl-N,N-dimethylbenzylamine; adipic acid dihydrazide, and sebacic acid dihydrazide; phosphorus compounds, such as triphenyl phosphine, etc. are mentioned. As what is marketed, 2 MZ-A by Shikoku Chemicals Corp. for example, 2 MZ-OK, 2PHZ, 2P4BHZ, 2P4MHZ (all are the trade names of an imidazole series compound), San Apro U-CAT (registered trademark) 3503N, U-CAT 3502T (all are the trade names of the block isocyanate compound of dimethylamine), DBU, DBN, U-CATSA102, U-CAT5002 (all are the trade names of 2 cyclic amidine compounds and its salt, guanamine, acetoguanamine, benzoguanamine, melamine, 2,4-diamino-6-methacryloiloxy-ethyl S-triazine, 2-vinyl-2,4-diamino-S-triazine, 2-vinyl-4,6-diamino-S-triazine isocyanuric acid adduct, S-triazine derivatives, such as 2,4-diamino-6-methacryloiloxy-ethyl S-triazine isocyanuric acid adduct; combinations thereof; and the like.

When present, the one or more catalysts may be present in an amount of about 0.2% (w/w) to about 2% (w/w), based upon the total weight of the Part A or Part B composition in which they are contained. In one embodiment, the catalysts may be present in an amount of about 1% (w/w), based upon the total weight of the Part A or Part B composition in which they are contained. For example, the catalysts may be present in an amount of about 0.2% to about 1.5%; or about 0.2% to about 1%; or about 0.2% to about 0.5%; or about 0.5% to about 2%; or about 0.5% to about 1.5%; or about 0.5% to about 1%; or about 1% to about 2%; or about 1% to about 1.5%; or about 1.5% to about 2%.

Photoresists commonly contain fillers, and compositions according to the current invention may optionally comprise fillers such as, but not restricted to, barium sulfate, spherical silica, fumed silica, hydrotalcite, kaolins, clays, organoclays, calcium carbonate, talc, alumina, etc.

The energy-curable compositions of the invention may also contain other components which enable them to perform in their intended application. These other ink components include, but are not restricted to, stabilizers, wetting aids, slip agents, inert resins, antifoams, fillers, rheological aids, amine synergists, etc.

When present, the one or more fillers may be present in an amount of about 5% (w/w) to about 50% (w/w), based upon the total weight of the Part A or Part B composition in which they are contained. In one embodiment, the fillers are present in an amount of about 15% (w/w), based upon the total weight of the Part A or Part B composition in which they are contained. For example, the fillers may be present in an amount of about 5% to about 45%; or about 5% to about 40%; or about 5% to about 35%; or about 5% to about 30%; or about 5% to about 25%; or about 5% to about 20%; or about 5% to about 15%; or about 5% to about 10%; or about 10% to about 50%; or about 10% to about 45%; or about 10% to about 40%; or about 10% to about 35%; or about 10% to about 30%; or about 10% to about 25%; or about 10% to about 20%; or about 10% to about 15%; or about 15% to about 50%; or about 15% to about 45%; or about 15% to about 40%; or about 15% to about 35%; or about 15% to about 30%; or about 15% to about 25%; or about 15% to about 20%; or about 20% to about 50%; or about 20% to about 45%; or about 20% to about 40%; or about 20% to about 35%; or about 20% to about 30%; or about 20% to about 30%; or about 20% to about 25%; or about 25% to about 50%; or about 25% to about 45%; or about 25% to about 40%; or about 25% to about 35%; or about 25% to about 30%; or about 30% to about 50%; or about 30% to about 45%; or about 30% to about 35%; or about 35% to about 50%; or about 35% to about 45%; or about 35% to about 40%; or about 40% to about 50%; or about 40% to about 45%; or about 45% to about 50%.

The photoresist compositions of the current invention are typically applied to a substrate, including any substrate used in the manufacture of electronic devices, such as Printed Circuit Boards (PCBs), both rigid and flexible. Any typical application method can be used, including, but not limited to, screen printing (both vertical and horizontal, manual, semi-automatic, and automatic screen machines), spray application (air spray and e-spray (vertical and horizontal)), curtain coating, roller and dip coating, etc. After application, the photoresist is imaged with a radiation source. Any radiation source producing an actinic effect may be used, such as, for example, UV, IR, daylight, EB, and gamma, with UV being preferred. The unexposed areas are then typically removed with a dilute alkaline (developing) solution.

Any suitable aqueous alkaline solution can be used as a developing solution. For example, aqueous alkali solutions of potassium hydroxide, sodium hydroxide, potassium carbonate, sodium carbonate, sodium phosphate, sodium silicate, ammonia, amines, etc. may be used. The concentration of alkali in the developing solution is generally about 0.1% to about 5% by weight. For example, the concentration of the alkali solution may be about 0.1% to about 4.5% by weight; or about 0.1% to about 4%; or about 0.1% to about 3.5%; or about 0.1% to about 3%; or about 0.1% to about 2.5%; or about 0.1% to about 2%; or about 0.1% to about 1.5%; or about 0.1% to about 1%; or about 0.1% to about 0.5%; or about 0.5% to about 5%; or about 0.5% to about 4.5%; or about 0.5% to about 4%; or about 0.5% to about 3.5%; or about 0.5% to about 3%; or about 0.5% to about 2.5%; or about 0.5% to about 2%; or about 0.5% to about 1.5%; or about 0.5% to about 1%; or about 1% to about 5%; or about 1% to about 4.5%; or about 1% to about 4%; or about 1% to about 3.5%; or about 1% to about 3%; or about 1% to about 2.5%; or about 1% to about 2%; or about 1% to about 1.5%.

It should be appreciated that, as well as developing the image with dilute alkaline aqueous solutions, the images may also be developed by removing the non-imaged areas with a suitable organic solvent. There is no restriction on the nature of the organic solvent used as a developing solution other than that it is an effective solvent for the uncured photoresist.

After being developed, and prior to the thermoset process, the resist may be subject to further treatments, such as further UV-curing. It should be noted that the compositions of the invention may be processed by all processing eventualities, and are not restricted to those described herein. The resist may then be cured further by a thermal treatment to induce reaction between the hardener resin and the carboxyl groups of the photosensitive resin. The thermal treatment is typically about 30 to about 90 minutes, at a temperature of about 130° C. to about 160° C.; preferably about 50 to about 70 minutes at 145° C. to about 155° C. The epoxy resin contained within the Part B of the inventive 2-pack composition also has the capacity to react with residual thiol provided by Part A of the 2-pack composition.

As noted previously, thiols react more rapidly with epoxies than do carboxylic acids and anhydrides. Therefore, compositions prepared according to the current invention have the capacity to achieve the desired levels of thermoset more quickly than has been previously disclosed in the prior art, and by what is achievable with commercially available photoresists. Thus, compositions according to the current invention, when formulated correctly in terms of thiol selection and thiol concentration, allow the thermoset reaction to be carried out at lower temperatures, or for shorter periods, or both.

It should be appreciated by those skilled in the art that, depending on the process and final properties required, there may be one or more UV-curing stages and one or more thermal treatments during the preparation of the final photoresist image. For example, a first UV-curing stage may be used to make the resist sufficiently robust prior to development with the dilute alkali solution. There then may follow a further UV-curing stage prior to the thermal curing stage.

### EXAMPLES

The following examples illustrate specific aspects of the present invention and are not intended to limit the scope thereof in any respect and should not be so construed. The examples are merely exemplary and are not to be construed as limiting the scope of subject matter claimed on the basis of the present disclosure. All parts and percentages are by weight (wt % or mass % based on the total weight).

### Example 1. Impact of Acid Value on Stability of Photoresist Compositions Comprising Thiol

To assess how the presence of carboxylic acid may influence the stability of thiol-containing compositions further comprising ethylenically unsaturated, especially polyacrylate functional, photoresist resins, specific blends of a carboxylic acid functional resist resin and an essentially acid-free resin were prepared. The carboxylic functional, ethylenically unsaturated resin (Resin 1) was a carboxylic acid functional proprietary epoxyacrylate resin derived from a cresol novolac type epoxy resin resin, used as a 67% (w/w) solution in ethyl diglycol acetate. The non-acid functional ethylenically unsaturated resin was SUN 30513254 (a proprietary acrylated cresol novolac epoxy resin). To these blends were added various amounts of trimethylolpropane tris(3-mercaptopropionate) (TMPMP), and in separate experiments either trimethylolpropane ethoxylate triacrylate, having 3 moles ethoxylation (TMPEOTA), or dipentaerythritol hexaacrylate (DPHA). The blends were then stored at 25° C. for 2 weeks; and any indication of the compositions gelling, or any significant thickening, was noted. In a separate experiment, the compositions were stored for 24 hours at 60° C., and again those compositions which gelled were recorded.

Table 1 provides the details of the compositions, along with their acid values, calculated on the basis of the data provided by the supplier, and the time taken for the compositions to gel.

TABLE 1
Impact of acid value on stability of photoresist compositions comprising thiols

| | Example | | | | | | | | | | | |
|---|---|---|---|---|---|---|---|---|---|---|---|---|
| | 1 | 2 | 3 | 4 | 5 | 6 | 7 | 8 | 9 | 10 | 11 | 12 |
| Resin 1 | 100 | 100 | 100 | 100 | 100 | — | — | 67 | 67 | 67 | 33 | 33 |
| SUN | — | — | — | — | — | 100 | 100 | 33 | 33 | 33 | 67 | 67 |
| 305132254 | | | | | | | | | | | | |
| TMPMP | — | 6 | 12 | 6 | 6 | — | 6 | — | 6 | 12 | — | 6 |
| TMPEOTA | — | — | — | 3 | — | — | — | — | — | — | — | — |
| DHPA | — | — | — | — | 3 | — | — | — | — | — | — | — |
| Acid value | 55 | 52 | 49 | 50 | 50 | <5 | <5 | 37 | 35 | 33 | 18 | 17 |
| (mg | | | | | | | | | | | | |
| KOH/g) | | | | | | | | | | | | |
| 1 day @ | OK | OK | OK | OK | OK | OK | Gel | OK | OK | OK | OK | OK |
| 25° C. | | | | | | | | | | | | |
| 8 days @ | OK | OK | OK | OK | OK | OK | Gel | OK | OK | OK | OK | Gel |
| 25° C. | | | | | | | | | | | | |
| 14 days @ | OK | OK | OK | OK | OK | OK | Gel | OK | OK | OK | OK | Gel |
| 25° C. | | | | | | | | | | | | |
| 1 day @ | OK | OK | OK | OK | OK | OK | Gel | OK | OK | OK | OK | Gel |
| 60° C. | | | | | | | | | | | | |

The results in Table 1 show that without any thiol, all the compositions were stable with no evidence of gelation, either at 25° C., or at 60° C. The compositions comprising thiol, and having acid values of 33 mg KOH/g, or greater, also showed no evidence of gelation through the course of the testing. The Example 7 composition, based solely on the non-carboxylic acid functional resin, SUN 30513254 and comprising TMPMP, gelled rapidly, within 24 hours when stored at 25° C., which is not considered adequate stability. This result shows how rapid the Michael addition reaction may occur without the presence of stabilising carboxylic acid. The Example 12 composition, with an acid value of 17 mg KOH/g, was stable for 24 hours at 25° C. but had gelled after 8 days storage at 25° C., which is acceptable stability for some applications.

Thus, it can be seen from the results presented in Table 1 that to gain stability with photoresist compositions comprising a thiol, according to the current invention, it is essential that a minimum amount of carboxylic acid be present to achieve the required stability. Preferred is an acid value greater than or equal to 15. More preferred is an acid value greater than or equal to 20.

### Example 2. Assessing the Performance of a 2-Pack Photoresist Composition Comprising Thiol

To determine the impact that a thiol has on the performance of a photoresist composition, a commercial 2-pack product, CAWS2437/NOPKS2278 (ex. Sun Chemical), with the addition of thiol (Inventive Examples 13-16), and without the addition of a thiol (Comparative Example 1) was evaluated. CAWS2437, is the photoresist component of the 2-pack composition and comprises a proprietary carboxy-functional ethylenically unsaturated resin, along with photoinitiators, colourant, defoamer, solvent, fillers, amongst other components. The acid value of this component of the 2-pack composition is about 26.5 mg KOH/g. CAWS2437 is mixed 2:1 with NOPKS2278 prior to printing, curing and processing to deliver the required final imaged product. NOPKS2278 is the hardener component of the 2-pack photoresist composition and comprises KEC-2185CA75, a polyepoxide resin, based on cresol novolac (ex. Kolon Industries), Epikote 1001, a polyepoxide resin based on Bisphenol A, along with SUN 30513254, and a number of other components. The epoxide groups of the reactive resins in the hardener component are able to react with the carboxylic acid (and thiol) contained within the photoresist component CAWS2437, during the thermoset stage of the imaging process.

To the CAWS2437 was added either 2 or 4% (w/w) of either TMPMP or pentaerythritol tetramercaptopropionate (PETMP) prior to blending with the hardener NOPKS2278 to produce the Inventive Examples 13-16. The blended compositions were then applied by manual flat-bed screen printing, onto copper clad FR4 laminate and unclad FR4 laminate using a composite squeegee, held for 10 minutes at room temperature to de-bubble, then dried in an oven for 40 minutes at 80° C. The prints were then photoimaged using a MIVA 2050L Direct Imager at different UV dose levels to produce the intended image. The UV-cured image was then developed with an alkaline solution consisting of 1% sodium carbonate solution in water, at about 33° C. for 60 seconds. After this developing stage the prints were then cured with a further UV dose of about 2000 mJ/cm² using a UVio Fusion UV Rig equipped with two medium pressure mercury UV lamps, followed by a bake cycle at 150° C. for 60 minutes in a box oven.

To determine the effectiveness of the inclusion of thiol into these 2-pack photoresist compositions, the degree of cure was assessed by the well-known Stouffer test, using a 21-step Stouffer test strip. A 21 step Stouffer test strip was placed on top of the coating of photoresist on the substrate. The test strip is a photographically shaded film with areas (“steps”) of different optical densities, from 100% total black (highest optical density) down to 100% total clear (lowest optical density). The lower number the step, the lower the optical density, and the more light that will be transmitted. For example, step 0 is completely clear (lowest optical density) and will transmit the most light, and step 21 is completely opaque (black) (highest optical density) and will transmit the least light. The photoresist was exposed through the test strip, at a known energy level. After exposure, the solder or photoresist mask was developed to remove unexposed (i.e. uncured) photoresist. Areas that were not washed off during the developing step were cured. Areas that were washed off during the developing step were not cured. A lower Stouffer step number means that everything up to the low optical density (e.g. 0 or 1) was washed off, and therefore not exposed to enough energy to cure the photoresist. As the dose level used to cure the film increases, more energy will be transmitted, and enough energy will be transmitted through higher optical densities (i.e. higher Stouffer numbers) to effectively cure the photoresist. Thus, a higher number not washed off means that there is more cure. The target Stouffer value for cure at the photoimaging stage is preferably a minimum of 4-5.

The photoresist coatings were cured at increasing energy levels of 50 mJ/cm², 100 mJ/cm², 150 mJ/cm², 200 mJ/cm², and 250 mJ/cm². The Stouffer number was recorded at each level of cure. The results are shown in Table 2.

As well as the Stouffer test, the 60° angle gloss of the printed image surface was measured by taking an average of 5 gloss readings across the panel using a Sheen minigloss 101N gloss meter before the alkali developing stage and after the final stoving stage. A significant loss of gloss indicates a poorly UV-cured surface.

Also, the amount of the photoimaged area (after UV-curing/photoimaging with the MIVA 2050L Direct Imager) that was removed during the developing stage with the dilute alkaline wash was also determined. In this case, the MIVA 2050L Direct Imager was used to image a series of 50 μm wide parallel ‘dams’ (a term well understood by those skilled in the art). The percentage of these dams remaining after the photoimaging stage is the figure recorded. In a most preferred embodiment, the % of dams remaining would be 100%

Table 2 provides the results of these various tests with the addition of the two thiols to the commercial CAWS2437/NOPKS2278 2-pack photoresist composition.

TABLE 2
Impact of inclusion of thiols on the performance
of a 2-pack photoresist composition

| | | | | Gloss; | | |
|---|---|---|---|---|---|---|
| | | | | Before | | Dams |
| | | | | Alkali | Final | Re- |
| | | UV-Dose | Stouffer | Developing | Gloss | maining |
| | Thiol | (mJ/cm²) | Rating | (%) | (%) | (%) |
| Comp. | None | 50 | 0-1 | 49.5 | 1.5 | 0 |
| Ex. 1 | | 100 | 2-3 | 51.1 | 4.8 | 66 |
| | | 150 | 4 | 50.6 | 7.4 | 53 |
| | | 200 | 5 | 51.7 | 8.8 | 62 |
| | | 250 | 6 | 50.4 | 12.2 | 100 |
| Inv. | 2% | 50 | 3-4 | 52.3 | 13.4 | 52 |
| Ex. 13 | TMPMP | 100 | 5-6 | 53.4 | 18.4 | 85 |
| | | 150 | 6-7 | 55.5 | 29.3 | 100 |
| | | 200 | 7-8 | 53.6 | 35.0 | 100 |
| | | 250 | 8-9 | 53.1 | 37.9 | 100 |
| Inv. | 4% | 50 | 4-5 | 55.9 | 19.6 | 100 |
| Ex. 14 | TMPMP | 100 | 6-7 | 56.3 | 40.5 | 100 |
| | | 150 | 7-8 | 55.8 | 41.8 | 100 |
| | | 200 | 8-9 | 55.5 | 43.8 | 100 |
| | | 250 | 9-10 | 53.4 | 43.5 | 100 |
| Inv. | 2% | 50 | 3-4 | 51.9 | 16.8 | 100 |
| Ex. 15 | PETMP | 100 | 5-6 | 54.6 | 33.9 | 93 |
| | | 150 | 7 | 53.0 | 34.4 | 100 |
| | | 200 | 7-8 | 52.9 | 38.0 | 100 |
| | | 250 | 8-9 | 52.4 | 40.6 | 100 |
| Inv. | 4% | 50 | 4-5 | 55.4 | 36.9 | 100 |
| Ex. 16 | PETMP | 100 | 6-7 | 54.0 | 41.3 | 100 |
| | | 150 | 8-9 | 54.8 | 45.6 | 100 |
| | | 200 | 9-10 | 56.9 | 47.4 | 100 |
| | | 250 | 9-10 | 57.9 | 50.4 | 100 |

The photoresist components (Part A) of all the inventive examples, with acid values of about 25 mg KOH/g are stable at 25° C. Again, this demonstrates that the presence of carboxylic acid stabilises the thiol component against Michael addition of the acrylate content of the photoresist.

The results in Table 2 clearly show the benefit of the inclusion of thiol on the UV-curing performance of the photoresist when cured using the low intensity UV-LED array of the MIVA 2050L Direct Imager. This is an important aspect of the current invention. The inclusion of either TMPMP or PETMP enables improved UV-cure, as evidenced by the Stouffer rating, the gloss of the final imaged print and also the dam retention. The improved gloss achieved with the inclusion of thiol results from an improvement in the surface cure during the photoimaging stage. This is an expected result as thiols are known to help overcome the impact of oxygen inhibition at surfaces of UV-cured inks and coatings. However, the improved through cure, as evidenced by the higher Stouffer rating of the compositions comprising thiol is surprising. This suggests that the incorporation of thiol enhances all aspects of the UV-cure of photoresists prepared and imaged according to the current invention.

Without the inclusion of any thiol, under the UV-cure achieved by the low intensity UV-LED array of the MIVA 2050L Direct Imager, even with a total dose of 250 mJ/cm², the properties of the final fully processed image were unsatisfactory. The inclusion of thiol enables final fully processed images with acceptable properties at doses as low as 100 mJ/cm², and even as low as 50 mJ/cm² in the case of Inventive Example 4.

### Example 3. Degree of Undercut for 100 μm Solder Dams Produced with an Initial Photoimaging Dose of 250 mJ/Cm²

In a further test, 100 μm solder dams of the Comparative 2-pack example and also Inventive Examples 2 and 4 were produced using an initial UV-cure dose of 250 mJ/cm² using the MIVA 2050L Direct Imager, followed by developing with the alkaline wash and thermal stoving steps as previously described. The lateral dimensions of the fully processed dams were then measured by taking microsections across the dams. From these measurements, the degree of undercut for each example was determined. The results for this assessment are provided in Table 3 below.

TABLE 3
Degree of undercut for 100 μm solder dams produced with an initial photoimaging dose of 250 mJ/cm²

| | Comparative | Inventive Example | Inventive Example |
|---|---|---|---|
| | Example 1 | 2 | 4 |
| | 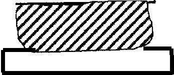 | 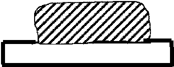 | 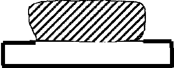 |
| Width at the top | 90.0 | 115.4 | 124.3 |
| of the dam (μm) | | | |
| Width at the middle | 91.8 | 114.5 | 124.6 |
| of the dam (μm) | | | |
| Width at the bottom | 66.5 | 107.0 | 109.1 |
| of the dam (μm) | | | |
| Undercut (μm) | 11.8 | 4.2 | 7.6 |

The results in Table 3 confirm the surprising finding that the incorporation of thiol into photoresist compositions prepared according to the current invention enhances not only the surface cure but also the through cure as evidenced by the significant reduction in undercut. It should be appreciated by those skilled in the art that any reduction in undercut is highly beneficial in the production of photoresist images and/or solder masks.

The present invention has been described in detail, including the preferred embodiments thereof. However, it will be appreciated that those skilled in the art, upon consideration of the present disclosure, may make modifications and/or improvements on this invention that fall within the scope and spirit of the invention.

1. An energy curable thermosetting resin composition comprising:
a) a carboxylic functional ethylenically unsaturated resin; and
b) an organosulphur compound;
wherein the acid value of the composition is equal to or greater than 10 mg KOH/g; and
wherein the composition is developable with an aqueous alkali solution, such that the uncured composition is removable by an aqueous alkali solution.

2. (canceled)

3. (canceled)

4. The composition of claim 1, wherein the organosulphur compound is a thiol or thioether.

5. The composition of claim 4, wherein the thiol is a mercaptan.

6. The composition of claim 1, further comprising a resin that is reactive with the carboxylic acid of the carboxylic functional ethylenically unsaturated resin.

7. The composition of claim 6, wherein the resin that is reactive with the carboxylic acid of the carboxylic functional ethylenically unsaturated resin is selected from the group consisting of polyepoxides, polyoxetane, an aminoresin, a blocked isocyanate, polyoxazoline, and polycarbodiimide.

8. The composition of claim 6, prepared as a 2-pack system, wherein:
a) Part A comprises a carboxylic functional ethylenically unsaturated resin and an organosulphur compound, wherein the acid value of Part A is equal to or greater than 10 mg KOH/g; and
b) Part B comprises a resin that is reactive with the carboxylic acid of Part A.

9. (canceled)

10. (canceled)

11. The composition of claim 1, wherein the carboxylic functional ethylenically unsaturated resin containing component of the composition comprises equal to or greater than 0.5% (w/w) of organosulphur compound.

12. The composition of claim 1, wherein the organosulphur compound is a thiol compound having 2 or more thiol groups per molecule.

13. The composition of claim 1, wherein the carboxylic acid functional ethylenically unsaturated resin is derived from the reaction of a polyfunctional epoxy resin, acrylic acid and/or methacrylic acid, and a polybasic carboxylic acid or anhydride.

14. The composition of claim 8, wherein the resin of Part B that is reactive with the carboxylic acid of Part A is selected from the group consisting of polyepoxides, polyoxetane, an aminoresin, a blocked isocyanate, polyoxazoline, and polycarbodiimide.

15. (canceled)

16. The composition of claim 1, further comprising one or more photoinitiators.

17. The composition of claim 16, wherein the photoinitiators can initiate free radical polymerization when exposed to UV-light in the 300 nm to 420 nm wavelength band.

18. The composition of claim 1, which is curable by UV-light generated by one or more UV-LED lamps; or which is curable by UV-light generated by one or more UV-lasers.

19. (canceled)

20. The composition of claim 1, which is curable with UV-light sources having peak irradiances of less than 8 W/cm².

21. (canceled)

22. (canceled)

23. The composition of claim 1, which is curable with a total UV dose of equal to or less than 300 mJ/cm².

24. (canceled)

25. (canceled)

26. The composition of claim 1, wherein the cured composition has an undercut of less than 10 μm after developing with an aqueous alkaline solution.

27. A substrate comprising the composition of claim 1.

28. The substrate of claim 27, wherein the substrate is a printed circuit board.

29. (canceled)

30. The substrate of claim 27, wherein the cured composition has an undercut of less than 10 μm after developing with an aqueous alkaline solution.

31. A method of preparing a printed circuit comprising:
a) providing a circuit board;
b) applying the composition of claim 1 on the circuit board;
c) curing exposed portions of the applied composition; and
d) developing the composition by removing the uncured portions of the composition with an aqueous alkaline solution.
